(19) United States
(12) Patent Application Publication
(10) Pub. No.: US 2026/0282784 A1
(43) Pub. Date: Sep. 17, 2026

(54) ETCHING METHOD, ETCHING APPARATUS, AND METHOD OF MANUFACTURING SEMICONDUCTOR DEVICE

(71) Applicant: Kioxia Corporation, Tokyo (JP)

(72) Inventors: Wu LI, Yokkaichi Mie (JP); Atsushi TERUYA, Yokohama Kanagawa (JP); Toshiyuki SASAKI, Yokkaichi Mie (JP); Shuichi KUBOI, Yokohama Kanagawa (JP); Kota TAMURA, Yokohama Kanagawa (JP)

(21) Appl. No.: 19/327,995

(22) Filed: Sep. 12, 2025

(30) Foreign Application Priority Data
Mar. 12, 2025 (JP) 2025-039736

(51) Int. Cl. H01L 21/311; C09K 13/00; C09K 13/08; H01J 37/32

(52) U.S. Cl. CPC H10P 50/283; C09K 13/00; C09K 13/08; H01J 37/3244; H01J 2237/002; H01J 2237/334

(57) ABSTRACT

A method for semiconductor device manufacturing and the like incorporates a high etch rate etching process. According to one embodiment, an etching method includes introducing a gas into a chamber comprising a first substance with hydrogen or a halogen component and a second substance comprising a hydroxy group. A plasma is generated in the chamber while a molecular density ratio of HF to H₂O in the chamber is kept at 0.3 or higher. A workpiece is then plasma etched while being cooled to a temperature of 0° C. or less.

### CROSS-REFERENCE TO RELATED APPLICATIONS

This application is based upon and claims the benefit of priority from Japanese Patent Application No. 2025-039736, filed Mar. 12, 2025, the entire contents of which are incorporated herein by reference.

### FIELD

Embodiments described herein relate generally to an etching method, an etching apparatus, and a method of manufacturing a semiconductor device.

### BACKGROUND

Among methods of manufacturing semiconductor devices, such as three-dimensional memories, a technique of forming an opening in a workpiece by a plasma etching technique, such as cryoetching, has been known.

### BRIEF DESCRIPTION OF THE DRAWINGS

FIG. 1 is a flowchart for illustrating an example of a method of manufacturing a semiconductor device.

FIG. 2 is a schematic cross-sectional view showing a structure example of a workpiece.

FIG. 3 is a schematic cross-sectional view for illustrating aspects of an etching step.

FIG. 4 is a schematic diagram illustrating a chemical reaction example in a cryoetching process.

FIG. 5 is a schematic diagram illustrating a chemical reaction example in a cryoetching process.

FIG. 6 depicts a semiconductor manufacturing apparatus that can be used for an etching step.

FIG. 7 is a graph depicting a relationship between sample temperatures and etching rates for silicon oxide films obtained in a first experiment.

FIG. 8 is a graph depicting a relationship between H₂O flow rate and residual molecular density ratio (HF/H₂O) in the first experiment.

FIG. 9 is a graph depicting a relationship between a gas flow rate ratio (H₂O/(H₂O+HF)) and an etching rate for a silicon oxide film (SiO₂).

FIG. 10 is a graph depicting a relationship between a gas flow rate ratio (H₂O/(H₂O+HF)) and an etching rate fora silicon nitride film (SiN).

FIG. 11 is a graph depicting a relationship between a workpiece cooling temperature and a ratio (etching rate ratio) of the etching rate for a third layer 105 compared to the etching rate for first layers 103 and second layers 104.

FIG. 12 is a schematic cross-sectional view illustrating aspects of a pillar forming step.

FIG. 13 is a schematic cross-sectional view illustrating aspects of a pillar.

### DETAILED DESCRIPTION

An object to be achieved is to provide an etching method with a higher etching rate.

In general, according to one embodiment, an etching method includes: introducing, into a chamber, a gas that comprises a first substance, including at least one of hydrogen or a halogen, and a second substance including a hydroxy group. A plasma is then generated in the chamber while maintaining a molecular density ratio of HF to H₂O (HF/H₂O) in the gas in the chamber at 0.3 or higher. A portion of a layer comprising silicon on a workpiece in the chamber is plasma etched while being cooled to a temperature of 0° C. or less.

Certain example embodiments are described below with reference to the drawings. It should be noted that, in general, the drawings are schematic and depicted relationships between various dimensions of the components and relative sizing of components are sometimes different from those adopted in actuality. In the description, those aspects that are substantially identical to one another are assigned the same reference symbol, and repeated description may be omitted after an initial introduction.

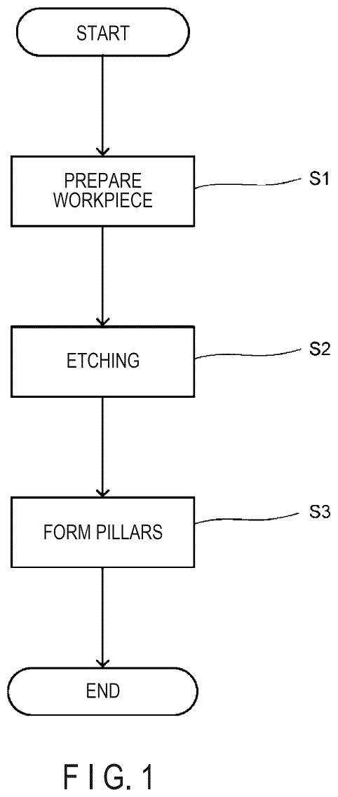

FIG. 1 is a flowchart for illustrating an example of a method of manufacturing a semiconductor device. The method includes an etching method according to an embodiment of the present disclosure. The semiconductor device formed in the method is, for example, a three-dimensional memory device. The example of the method of manufacturing the semiconductor device includes: a workpiece preparing step (S1); an etching step (S2); and a pillar forming step (S3).

### Workpiece Preparing Step

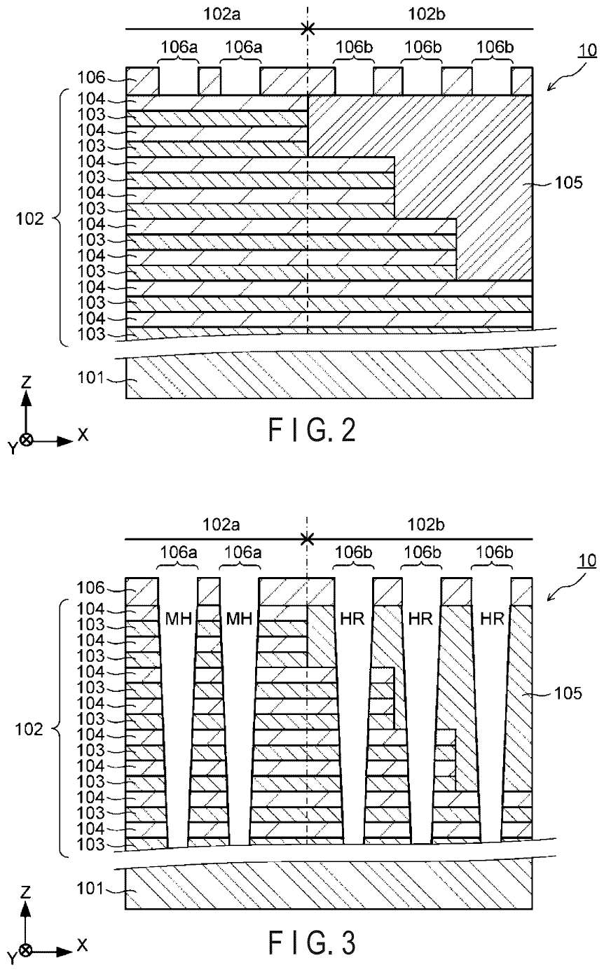

In the workpiece preparing step, a workpiece that is to be etched in the etching step is prepared. FIG. 2 is a schematic cross-sectional view showing a structure example of the workpiece. FIG. 2 shows part of an X-Z planar cross-section of a workpiece 10. The Z axis is along the thickness direction of the workpiece 10.

The workpiece 10 includes: a substrate 101; a stacked body 102 provided on the substrate 101; first layers 103 and second layers 104 that are provided in the stacked body 102; a third layer 105 provided on the stacked body 102; and a mask layer 106 provided on the stacked body 102 and on the third layer 105. The first layers 103, the second layers 104, and the third layer 105 are examples of films that are provided on the substrate 101 and are to be processed. The films to be processed are not limited to those having the configuration described above. A foundation (base) layer may be formed between the substrate 101 and the stacked body 102. The foundation layer may be, for example, an insulating film, such as a silicon oxide film or a silicon nitride film, or a conductive layer between insulating films. The workpiece 10 shown in FIG. 2 can be formed by a well-known method.

Examples of the substrate 101 include: semiconductor substrates, such as a silicon substrate or a silicon carbide substrate; insulating substrates, such as a glass substrate, quartz substrate, or a sapphire substrate; and compound semiconductor substrates, such as a GaAs substrate.

Each first layer 103 is a sacrificial layer. The sacrificial layer (103) is present in a region where a conductive layer is to be formed later (in a subsequent process). The first layer 103 comprises silicon and nitrogen. Examples of the first layer 103 include a silicon nitride film or the like.

Each second layer 104 is an insulating layer. The second layer 104 comprises silicon and oxygen. Examples of the second layer 104 include a silicon oxide film or the like.

The first layers 103 and the second layers 104 are alternately stacked in the Z-axis direction, and include a stacked portion 102a (fully stacked portion) and a stacked portion 102b (partially stacked portion).

In stacked portion 102a all the first layers 103 and all the second layers 104 of the stacked body 102 are stacked in the Z-axis direction one upon the other. The stacked portion 102a is, for example, a region where pillars (also called memory pillars) for memory cells are formed.

The stacked portion 102b is provided at an end or edge of the stacked portion 102a in the X-axis direction or the Y-axis direction. The stacked portion 102b has a stairstep structure in which some of the first layers 103 and second layers 104 in the stacked portion 102a are removed or not present. The stairstep structure has the first layers 103 and the second layers 104 in the stacked body 102 formed into steps (stepwise). The stacked portion 102b is a region where electrical contacts and pillars penetrating through the stacked body 102 for maintaining the mechanical strength are formed.

The third layer 105 is provided on the stacked portion 102b so as to fill the recessed (stairstep) portions on the stacked portion 102b. The third layer 105 is an insulating layer. The third layer 105 comprises silicon and oxygen. Examples of the third layer 105 include a silicon oxide film.

The mask layer 106 is provided on the stacked body 102 and the third layer 105. The mask layer 106 has a function as a mask for etching part of the stacked body 102. The mask layer 106 may be, for example, an organic hard mask or the like. Note that the mask layer 106 may be removed after parts of the stacked body 102 and the third layer 105 are etched.

The mask layer 106 has openings 106a that overlap the stacked portion 102a in the Z-axis direction, and openings 106b that overlap the stacked portion 102b in the Z-axis direction. The openings 106a are provided so as to overlap the regions of the stacked portion 102a where the pillars are formed in the Z-axis direction. The openings 106b are provided so as to overlap the regions of the stacked portion 102b where the pillars are formed in the Z-axis direction. FIG. 2 shows a plurality of openings 106a, and a plurality of openings 106b. However, the number of openings 106a and the number of openings 106b are not limited to the number of openings 106a and the number of openings 106b shown in FIG. 2.

### [Etching Step]

FIG. 3 is a schematic cross-sectional view for illustrating the etching step. FIG. 3 shows part of an X-Z section of the workpiece 10. In the etching step, at least one opening is formed by partially etching the workpiece 10 by plasma etching. FIG. 3 shows an example of simultaneously forming openings MH and openings HR. However, there is no limitation to such a simultaneous case. Either the openings MH or the openings HR, or other openings may be formed.

The openings MH overlap the stacked portion 102a in the Z-axis direction. The openings MH extend in the Z-axis direction in the stacked portion 102a. Note that the widths of the openings MH in FIG. 3 decrease from the respective openings 106a toward the substrate 101. However, there is no limitation to this. The widths may be uniform.

The openings HR overlap the stacked portion 102b in the Z-axis direction. The openings HR extend in the third layer 105 and the stacked portion 102b in the Z-axis direction. Note that the widths of the openings HR in FIG. 3 decrease from the respective openings 106b toward the substrate 101. However, there is no limitation to this. The widths may be uniform.

Examples of plasma etching include cryoetching. Cryoetching is plasma etching that is performed in a state where the workpiece 10 is cooled at a temperature of 0° C. or lower.

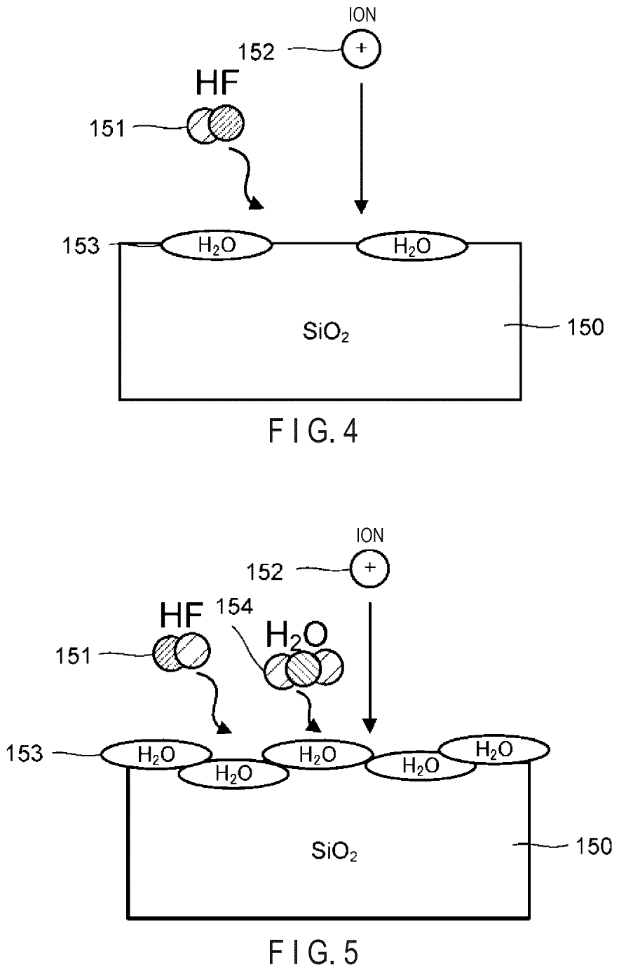

FIGS. 4 and 5 are schematic diagrams for illustrating chemical reaction examples by cryoetching. Here, for example, a case of generating plasma from hydrogen fluoride gas and etching the silicon oxide film is exemplified.

Plasma is generated from hydrogen fluoride gas and cryoetching is performed, thus allowing the surface of a silicon oxide film 150 to be etched by plasma ions 152 generated from hydrogen fluoride 151. Furthermore, as shown in FIG. 4, water 153 is formed, and hydrogen fluoride is dissolved in water 153, which can increase the fluorine concentration on the surface, and improve the etching rate. However, the amount of water generation is small. Accordingly, for example, in a case of forming openings having a high aspect ratio, it is difficult to significantly improve the etching rate for the silicon oxide film.

On the other hand, when hydrogen fluoride and water are both supplied and cryoetching is performed, the surface of the silicon oxide film 150 can also be etched by the plasma ions 152 generated from the hydrogen fluoride 151. Also, as shown in FIG. 5, on the surface of the silicon oxide film 150, the concentration of water 153 is increased, and thus the hydrogen fluoride dissolved in the water is increased, which can further increase the fluorine concentration on the surface, and further improve the etching rate for the silicon oxide film 150.

In the present embodiment, a gas that contains a first substance comprising at least one of hydrogen or a halogen and a second substance comprising a hydroxy group (OH group) is supplied into the chamber. Cryoetching is then performed while regulating the ratio of HF to H₂O in the chamber, thereby facilitating improvement in the etching rate.

### (Etching Apparatus)

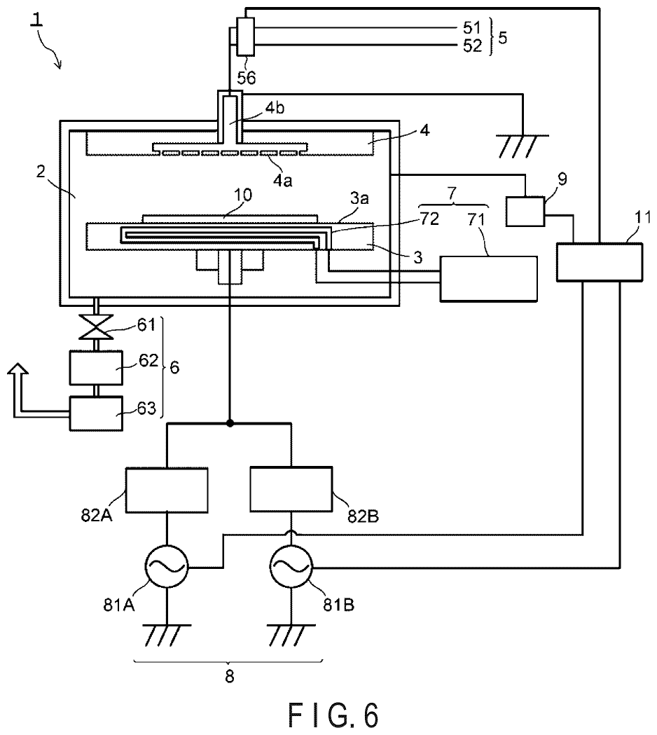

FIG. 6 is a schematic diagram showing a configuration example of a semiconductor manufacturing apparatus (etching apparatus) that can be used for the etching step described above. FIG. 6 schematically shows a configuration example of a plasma etching apparatus 1.

The plasma etching apparatus 1 includes a chamber 2, an electrode 3, an electrode 4, a supplier 5, an exhaust unit 6, a cooling unit 7, a power source unit 8, a mass spectrometer 9, and a controller 11.

The chamber 2 defines a space that allows the workpiece 10 to be etched (plasma etched). Note that the chamber 2 may have a door (gate) for loading and unloading the workpiece 10.

The electrode 3 is disposed in the chamber 2. The electrode 3 is a lower electrode, and has a function as a mounting stage on which the workpiece 10 is mounted. The electrode 3 has a surface 3a that is a mounting surface for the workpiece 10. Note that the etching apparatus 1 may have an electrostatic chuck for holding the workpiece 10.

The electrode 4 is disposed in the chamber 2. The electrode 4 is an upper electrode. The electrode 4 has a surface 4a, and an opening 4b for allowing the gas to be introduced into the chamber 2 through the electrode 4. The opening 4b has a plurality of entry ports in the surface 4a.

The supplier 5 includes, for example, a raw material supply source 51 that supplies the first substance, and a raw material supply source 52 that supplies the second substance. The first substance and the second substance are different from each other. The raw material supply source 51 and the raw material supply source 52 are each connected to the chamber 2. The supplier 5 further includes a flow rate regulating unit 56 that includes a plurality of mass flow controllers. The flow rates of gases of the first substance and the second substance can be respectively controlled by the corresponding mass flow controllers.

The examples of the raw material supply source 51 and the raw material supply source 52 include a cylinder cabinet and the like. The supplier 5 supplies a first gas derived from the first substance and a second gas derived from the second substance, respectively from the raw material supply source 51 and the raw material supply source 52 to the chamber 2. Note that in the embodiment, the example with the plurality of raw material suppliers is described. However, the number of raw material suppliers may be one. For example, one raw material supplier may supply both the first substance and the second substance.

The first substance comprises at least one of hydrogen and a halogen. The first substance may comprise both hydrogen and a halogen. The halogen can be, for example, fluorine (F). The first substance may be a liquid or a gas. When the first substance is a liquid, the first substance can be heated by a heating device, such as a heater provided for the raw material supply source 51, and the gasified first substance can be used as a first gas. When the first substance is a gas, the first substance can be used directly as the first gas.

A hydrogen-containing first substance can be, for example, at least one of hydrogen (H₂), hydrogen fluoride (HF), fluoromethane (CH₃F), difluoromethane (CH₂F₂), trifluoromethane (CHF₃), ammonia (NH₃), and phosphine (PH₃).

A halogen-containing first substance can be, for example, at least one of boron trifluoride (BF₃), carbon tetrafluoride (CF₄), trifluoroacetic acid (CF₃COOH), nitrogen trifluoride (NF₃), sulfur hexafluoride (SF₆), tungsten hexafluoride (WF₆), chlorine (Cl₂), hydrogen chloride (HCl), boron trichloride (BCl₃), carbon tetrachloride (CCl₄), silicon tetrachloride (SiCl₄), hydrogen bromide (HBr), dibromofluoromethane (CHFBr₂), iodine pentafluoride (IF₅), iodine heptafluoride (IF₇), phosphorus trifluoride (PF₃), phosphorus pentafluoride (PF₅), phosphorus trichloride (PCl₃), and phosphorus tribromide (PBr₃).

The first substance may be a mixture of a hydrogen-containing first substance(s) and a halogen-containing first substance(s). The first substance may further comprise one or more noble gas, such as argon (Ar), helium (He), xenon (Xe), or krypton (Kr).

The second substance has a hydroxy group (OH group). The second substance may be a liquid or a gas. When the second substance is a liquid, the second substance can be heated by a heating device, such as a heater provided for the raw material supply source 52, and the gasified second substance can be used as a second gas. When the second substance is a gas, the second substance can be used directly as the second gas.

The second substance comprises, for example, at least one of water (H₂O), hydrogen peroxide (H₂O₂), methanol (CH₃OH), ethanol (CH₃CH₂OH), trifluoroethanol (CF₃CH₂OH), or trifluoroacetic acid (CF₃COOH).

In an embodiment, the first substance is CHF₃ and the second substance is H₂O. In another example, the first substance is a mixture of HF and PF₃ and the second substance is H₂O.

The exhaust unit 6 has a function of reducing the pressure in the chamber 2 to achieve a vacuum state, and can exhaust the gas from the chamber. The exhaust unit 6 includes a valve 61, a turbomolecular pump 62, and a dry pump 63 installed in an exhaust pipe.

The cooling unit 7 includes, for example, a chiller 71, and a refrigerant pipe 72 in the electrode 3. The chiller 71 circulates refrigerant through the refrigerant pipe 72, thus cooling the workpiece 10. The cooling temperature for the workpiece 10 can be, for example, 0° C. or lower, −20° C. or lower, or −50° C. or lower.

The power source unit 8 supplies (applies) an AC voltage to the electrode 3 in the chamber 2. The power source unit 8 includes a power source 81A, a power source 81B, a matching circuit 82A, and a matching circuit 82B. The power sources 81A and 81B are connected to the controller 11. The matching circuit 82A and the matching circuit 82B comprises, for example, a matching box.

The power source 81A has a function of matching the impedance between the chamber 2 and the power source 81A through the matching circuit 82A, and applying, for example, a first AC voltage having a first frequency of 27 MHz to 100 MHz to the electrode 3. By controlling the first frequency within this numerical range, the plasma density can be controlled.

The power source 81B has a function of matching the impedance between the chamber 2 and the power source 81B through the matching circuit 82B, and applying, for example, a second AC voltage having a second frequency of 100 kHz to 3 to the electrode 3. By controlling the second frequency within this numerical range, the energy of incident ions can be controlled.

The mass spectrometer 9 analyzes the gas in the chamber 2. For example, the mass spectrometer 9 measures the ratio (residual molecular density ratio G1/G2) of the molecular density of a gas G1 and that of a gas G2 in the chamber 2 during plasma etching. In this case, G1 (a component of the first gas) is, for example, HF, and G2 (a component of the second gas) is, for example, H₂O. Here, the first gas and the second gas in the chamber 2 during plasma etching comprise a component that is consumed by a chemical reaction with the surface of the workpiece 10 and thus generally decreases during plasma processing, and a component that is generated by a chemical reaction with the surface of the workpiece 10 during plasma processing.

The mass spectrometer 9 includes, for example, a quadrupole mass spectrometer (OMS). The QMS permits measurement of the residual molecular density ratio (G1/G2) during plasma etching. Data of the measured residual molecular density ratio (G1/G2) is transmitted to, for example, the controller 11.

The controller 11 controls the supplier 5, the exhaust unit 6, the cooling unit 7, the power source unit 8, and the mass spectrometer 9. The controller 11 in this example includes hardware such as, for example, a processor. Note that instructions for each described operation or function may be stored as software or program instructions of an operating program in a non-transitory, computer-readable recording medium, such as a solid-state memory, and the operating program thus stored in the recording medium may be read by hardware as appropriate for executing each described operation or function.

### (Etching Method)

The etching method in an embodiment supplies the chamber 2 with a first gas of a first substance (comprising hydrogen or a halogen) and a second gas of a second substance (comprising a hydroxy group). An AC voltage applied by supplying the first AC voltage and the second AC voltage to the electrode 3 in a superimposed manner generates plasma from the gas in the chamber 2, which etches (plasma etches) part of the workpiece 10 that is cooled to a temperature of 0° C. or lower in the chamber 2.

According to an etching method in an embodiment, it is preferable that the residual molecular density ratio (HF/H₂O) be between 0.3 and 6.0.

The residual molecular density ratio (G1/G2) can be regulated by measuring the residual molecular density ratio (G1/G2) using the mass spectrometer 9 during plasma etching, and then optimizing, at least one parameter from among the pressure in the chamber 2, the density of power supplied to the chamber 2, the flow rate of the first gas, and the flow rate of the second gas. At least one such parameter can be regulated, for example, by the controller 11 controlling the supplier 5, the exhaust unit 6, the cooling unit 7, the power source unit 8, and/or the mass spectrometer 9 during plasma etching.

For example, when supplying HF as the first gas and H₂O as the second gas and performing plasma etching, thermoelectrons emitted from a heated filament in the QMS collide with HF and H₂O in the gas in a plasma processing vessel, thus ionizing some of these molecules to HF+ and H₂O+. These ions can be separated and detected by the quadrupole mass spectrograph installed in the QMS. The ratio of acceptance intensities of HF⁺ to H₂O⁺ (HF⁺/H₂O⁺) can be taken as substantially equivalent to the residual molecular density ratio (HF/H₂O) in the plasma processing vessel.

### (First Experiment)

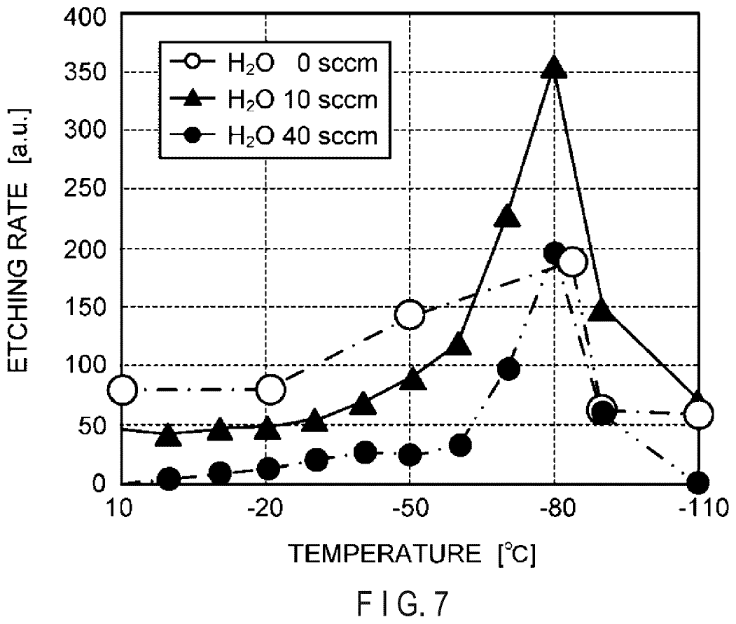

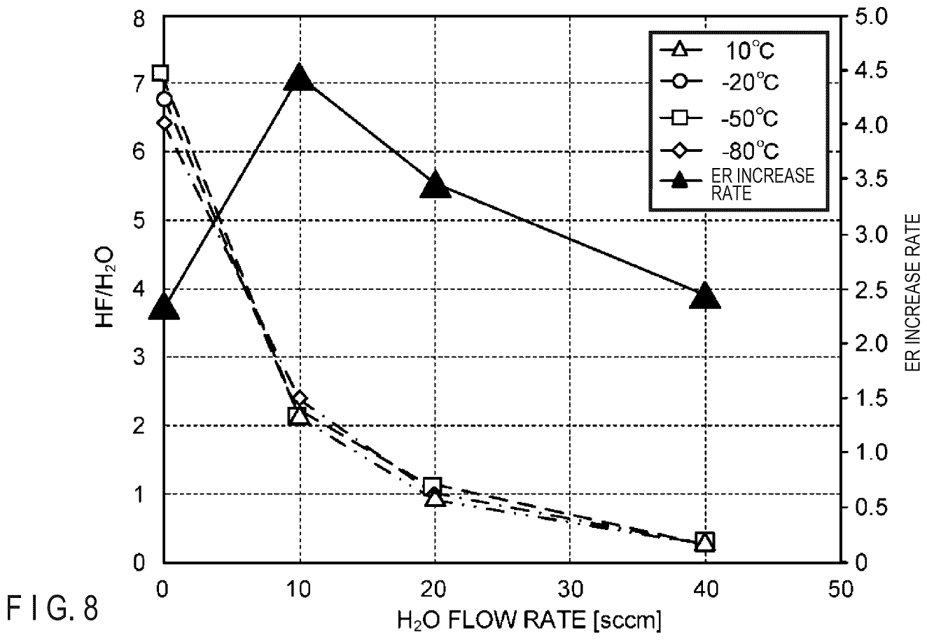

FIG. 7 is a graph showing a relationship between the temperatures of samples and the etching rates of silicon oxide films obtained from a result of a first experiment with conditions shown in Table 1. The first experiment is performed by etching a plurality of samples that include silicon oxide films on wafers using the plasma etching apparatus in the embodiment. Each condition of the first experiment is shown in Table 1. FIG. 8 shows cases where the flow rate of H₂O is 0 sccm, 10 sccm, and 40 Sccm.

As shown in FIG. 7, when supplying CHF₃ as the first gas and H₂O as the second gas, the etching rate is maximized at a cooling temperature of around −80° C., for example. On the other hand, when no H₂O is supplied (i.e., the flow rate of H₂O is 0 sccm), the increase in etching rate is smaller than when the flow rate of H₂O is 10 sccm. This is because the amount of H₂O is insufficient.

TABLE 1
First experiment

| Chamber pressure | 30 mTorr (3.99 Pa) | |
|---|---|---|
| Voltage frequency (high/low) | 60/2 | MHz |
| Power (high/low) | 400/500 | W |
| Stage diameter | Φ100 | mm |

| | |
|---|---|
| Power density (high/low) | 5.1/6.3 W/cm² |
| Gas flow rate | CHF₃/H₂O = 27/0-40 sccm |

FIG. 8 is a graph showing the relationship between the H₂O flow rate and the residual molecular density ratio (HF/H₂O) obtained in the first experiment. The residual molecular density ratio (HF/H₂O) is the ratio of the molecular density of HF to the molecular density of H₂O in chamber 2 during plasma etching. FIG. 8 further shows the relationship between the residual molecular density ratio (HF/H₂O) and the rate of increase in etching rate (ER increase rate). The etch rate (ER) increase rate is calculated based on the ratio of a silicon oxide film etching rate when supplying H₂O to a silicon oxide film etching rate when no H₂O is supplied. FIG. 8 shows cases where the temperature of the sample is 10° C., −20° C., −50° C., and −80° C.

As shown in FIG. 8, when the residual molecular density ratio (HF/H₂O) is 0.3 or higher, the etching rate increases in comparison with the case of no H₂O being supplied, and when the residual molecular density ratio (HF/H₂O) is 2, the rate of increase in etching rate is at the maximum. Consequently, the result of the first experiment shows that it is preferable that the residual molecular density ratio (HF/H₂O) be between 0.3 and 6.0.

Furthermore, as shown in FIG. 3, in a case of simultaneously forming the openings MH and the openings HR by cryoetching in the stacked body 102 of silicon containing films having different compositions, it is preferable that the etching rates in the film forming regions be as close to each other as possible. In particular, since the third layer 105 is thicker than the first layer 103 and the second layer 104, it is preferable to increase the etching rate for the third layer 105.

While the description above focuses on the residual molecular density ratio (G1/G2) in the chamber 2 during plasma etching, the etching rate may be controlled by regulating the ratio of flow rates of the first gas and the second gas being supplied into the chamber 2. The flow rates of the first gas and the second gas can be regulated by, for example, mass flow controllers of the flow rate regulating unit 56.

### (Second Experiment)

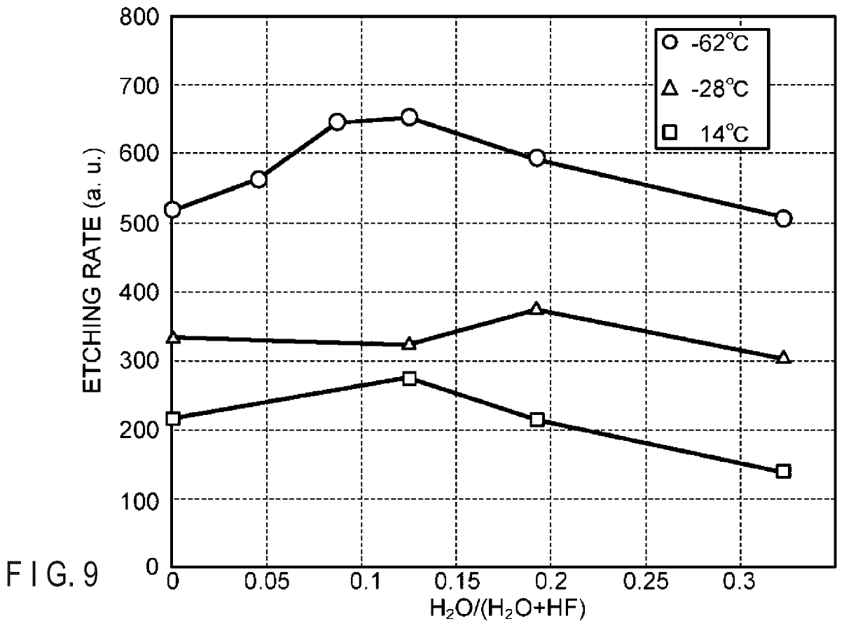

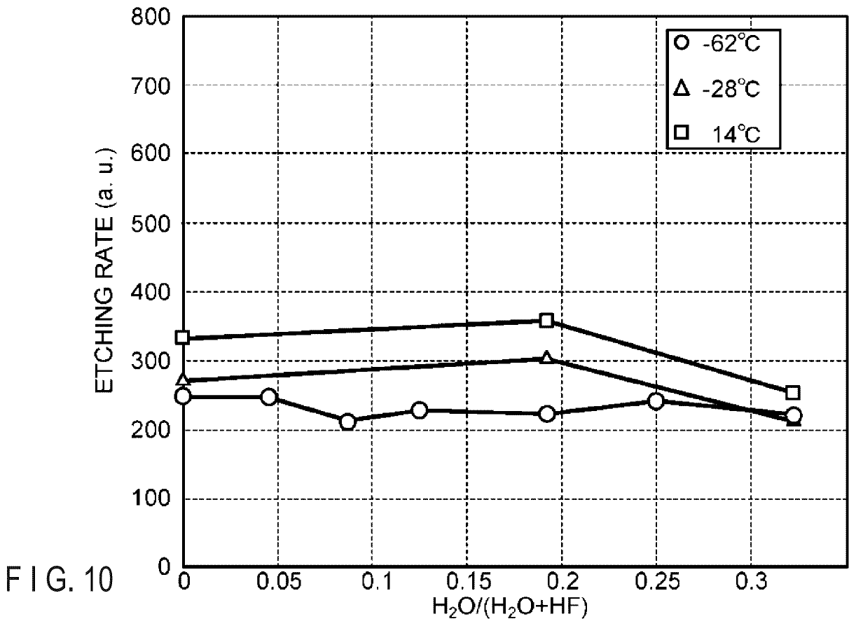

FIG. 9 is a graph showing the relationship between the gas flow rate ratio (H₂O/(H₂O+HF)) as calculated in a second experiment with conditions shown in Table 2 and the etching rate for a silicon oxide film (SiO₂). The gas flow rate ratio (H₂O/(H₂O+HF)) is the flow rate ratio of the H₂O flow to the sum of H₂O flow and HF flow into the chamber 2. FIG. 10 is a graph showing the relationship between the gas flow rate ratio (H₂O/(H₂O+HF)) as calculated in the second experiment and the etching rate for a silicon nitride film (SiN).

The second experiment is performed by separately etching a plurality of first samples (containing silicon oxide films) on wafers, and a plurality of second samples (containing silicon nitride films) on wafers, using the plasma etching apparatus. Conditions for the second experiment are shown in Table 2. In the second experiment, a mixture of HF and PF₃ (as the first gas) and H₂O (as the second gas) are used. FIGS. 9 and 10 show cases where the cooling temperatures are 14° C., −28° C., and −62° C.

TABLE 2
Second experiment

| Chamber pressure | 18 mTorr (2.39 Pa) | |
|---|---|---|
| Voltage frequency (high/low) | 60/0.4 | MHz |
| Power (high/low) | 139/340 | W |
| Stage diameter | Φ30 | mm |

| | |
|---|---|
| Power density (high/low) | 19.8/48.5 W/cm² |
| Gas flow rate | HF/PF₃/H₂O = 21/1.8/0-5 sccm |

As shown in FIGS. 9 and 10, when the gas flow rate ratio (H₂O/(H₂O+HF)) is between 0.05 and 0.2 (endpoints inclusive), the etching rate for the silicon oxide film can be increased in comparison to the etching rate for the silicon nitride film. The lower the wafer cooling temperature, the more significant the increase in etching rate.

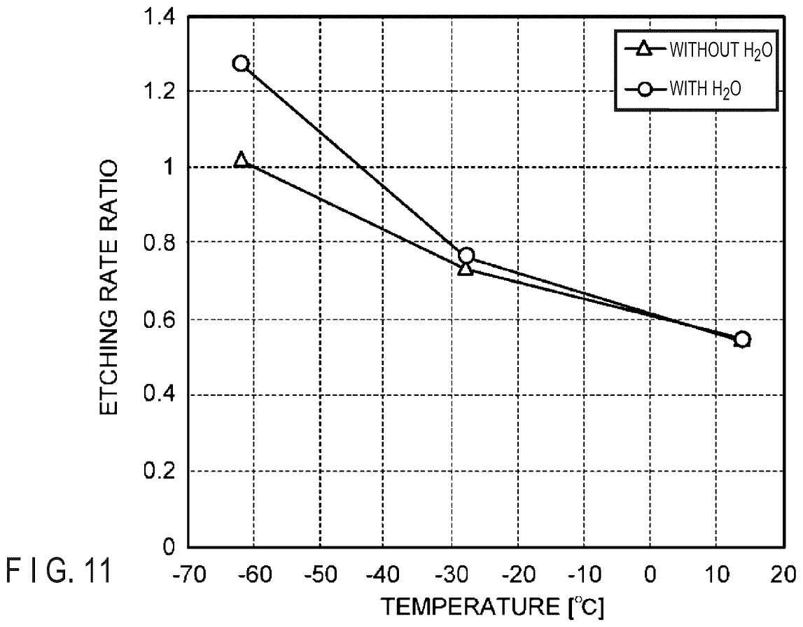

FIG. 11 is a graph showing the relationship between the cooling temperature for the workpiece 10, and the ratio (etching rate ratio) for the etching rate for the third layer 105 to the first layers 103 and the second layers 104, as calculated from the results of the second experiment. That is, the ordinate axis indicates the ratio between the etching rate for the stacked films of the silicon nitride film and the silicon oxide film, and the etching rate for a single layer of the silicon oxide film. With reference to FIG. 11, the case of supplying H₂O (with H₂O) can bring the etching rate ratio close to one (i.e., equivalent etch rates) without bringing the workpiece 10 to a very low temperature in comparison to the case of not supplying H₂O (no H₂O). For example, in the case of cooling the workpiece 10 at −30° C. or lower, more preferably, cooling it at a temperature of around −45° C., the etching rate ratio can be substantially equal to one. Consequently, the power required for cooling can be reduced.

As described above, a gas that is comprised of the first substance (containing at least one of hydrogen or a halogen) and the second substance (containing a hydroxy group) is supplied to the chamber, plasma is generated while maintaining the residual molecular density ratio between HF and H₂O in the gas inside the chamber to be within a predetermined numerical range, which can increase the etching rate for the workpiece 10 (cooled at a temperature of 0° C. or lower) by plasma etching. Accordingly, for example, even in the case of forming openings with a high aspect ratio, the etching rate can be increased, and a high-rate etching of the workpiece 10 can be achieved.

### (Pillar Forming Step)

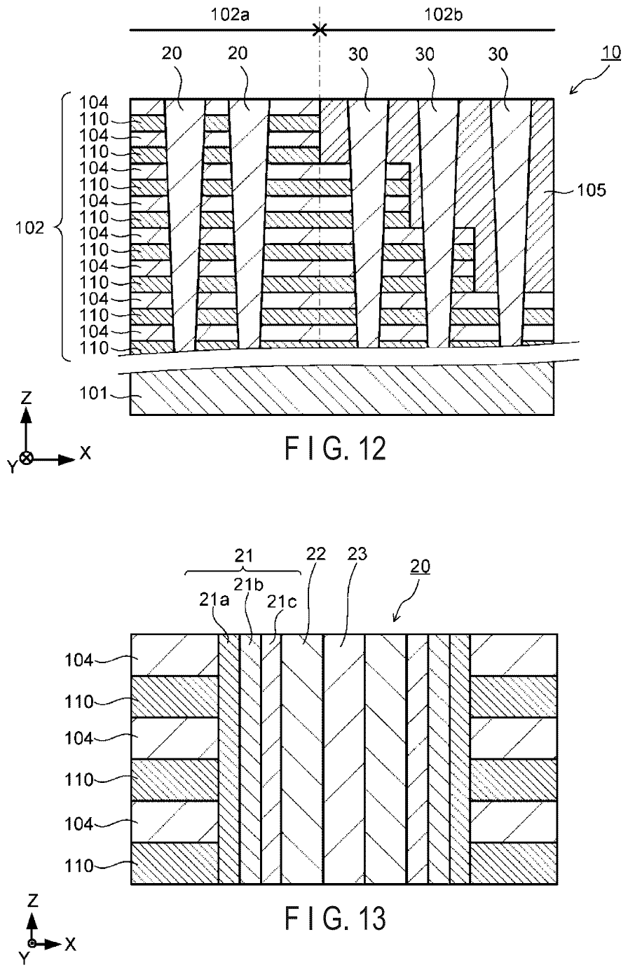

FIG. 12 is a schematic cross-sectional view for illustrating the pillar forming step. FIG. 12 shows part of an X-Z section of the workpiece 10. The pillar forming step forms pillars 20 in the respective openings MH, and forms pillars 30 in the respective openings HR.

FIG. 13 is a schematic cross-sectional view for illustrating a structure example of the pillar 20. FIG. 13 shows part of the X-Z section of the pillar 20. The pillar 20 includes a memory layer 21, a semiconductor layer 22, and a core insulator 23.

The memory layer 21 includes a block insulating film 21a, a charge storage film 21b, and a tunnel insulating film 21c. The block insulating film 21a and the tunnel insulating film 21c contain, for example, silicon oxide. The charge storage film 21b includes, for example, silicon nitride. The memory layer 21 constitutes a memory cell in the stacked portion 102a.

The semiconductor layer 22 penetrates through the stacked body 102 along the Z-axis direction. The outer periphery of the semiconductor layer 22 is covered with the memory layer 21. The semiconductor layer 22 comprises, for example, polycrystalline silicon.

The core insulator 23 is provided inside the semiconductor layer 22. The core insulator 23 extends along the semiconductor layer 22. The core insulator 23 comprises, for example, silicon oxide.

An insulator, as the pillar 30, is formed in the opening HR. The insulator comprises, for example, silicon oxide.

After the pillars 20 and the pillars 30 are formed, the first layers 103 are removed, thus leaving hollow spaces (voids) between the second layers 104. A plurality of conductive films are formed in the hollow spaces, thereby forming conductive layers 110. Each conductive layer 110 functions, for example, as a gate electrode (or a word line). Furthermore, contact plugs, wiring, an inter-layer insulating film and the like are formed on the stacked body 102. Thus, the semiconductor device can be manufactured.

As the example in the present embodiment, the opening is a memory hole in which a memory layer is formed. However, the present disclosure is not limited to formation of a memory hole. Other various openings, such as grooves (ST) for a sacrificial layer to be replaced with the conductive layers 110 or holes for contact plugs to be connected to the conductive layers 110 may be similarly formed according to the present disclosure.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. An etching method, comprising:
introducing a gas into a chamber, the gas comprising a first substance and a second substance, the first substance including at least one of hydrogen or a halogen, the second substance including a hydroxy group;
generating plasma in the chamber with the gas therein while maintaining a molecular density ratio of HF to H₂O (HF/H₂O) for the gas in the chamber at 0.3 or higher; and
plasma etching a portion of a layer on a workpiece in the chamber while the workpiece is being cooled to a temperature of 0° C. or less, the layer comprising silicon.

2. The etching method of claim 1, further comprising:
maintaining the molecular density ratio (HF/H₂O) for the gas in the chamber at 0.3 to 6.0.

3. The etching method of claim 1, further comprising:
introducing the gas into the chamber while maintaining a flow rate ratio of H₂O to HF and H₂O (H₂O/(HF+H₂O)) in the gas being introduced to be 0.05 to 0.2.

4. The etching method of claim 1, wherein the molecular density ratio is measured using a quadrupole mass spectrometer.

5. The etching method of claim 1, wherein the first substance comprises at least one material selected from a group consisting of hydrogen, hydrogen fluoride, fluoromethane, difluoromethane, trifluoromethane, ammonia, and phosphine.

6. The etching method of claim 1, wherein the first substance is a material selected from a group consisting of hydrogen, hydrogen fluoride, fluoromethane, difluoromethane, trifluoromethane, ammonia, and phosphine.

7. The etching method of claim 1, wherein the first substance includes at least one material selected from a group consisting of boron trifluoride, carbon tetrafluoride, trifluoroacetic acid, nitrogen trifluoride, sulfur hexafluoride, tungsten hexafluoride, chlorine, hydrogen boron chloride, trichloride, carbon tetrachloride, silicon tetrachloride, hydrogen bromide, dibromofluoromethane, iodine pentafluoride, iodine heptafluoride, phosphorus trifluoride, phosphorus pentafluoride, phosphorus trichloride, and phosphorus tribromide.

8. The etching method of claim 1, wherein the first substance is a material selected from a group consisting of boron trifluoride, carbon tetrafluoride, trifluoroacetic acid, nitrogen trifluoride, sulfur hexafluoride, tungsten hexafluoride, chlorine, hydrogen chloride, boron trichloride, carbon tetrachloride, silicon tetrachloride, hydrogen bromide, dibromofluoromethane, iodine pentafluoride, iodine heptafluoride, phosphorus trifluoride, phosphorus pentafluoride, phosphorus trichloride, and phosphorus tribromide.

9. The etching method of claim 1, wherein the second substance includes at least one material selected from a group consisting of water, hydrogen peroxide, methanol, ethanol, trifluoroethanol, and trifluoroacetic acid.

10. The etching method of claim 1, wherein the second substance is a material selected from a group consisting of water, hydrogen peroxide, methanol, ethanol, trifluoroethanol, and trifluoroacetic acid.

11. The etching method of claim 1, wherein
a first AC voltage having a first frequency between 27 MHz and 100 MHz is applied to an electrode, and
a second AC voltage having a second frequency between 100 kHz and 3 MHz is applied to the electrode in a superimposed manner with the first AC voltage.

12. The etching method of claim 1, wherein the layer on the workpiece is one of a first layer comprising silicon and nitrogen, a second layer comprising silicon and oxygen, or a stacked body comprising alternating first layers and second layers.

13. The etching method of claim 1, wherein
the workpiece comprises:
a substrate;
a stacked body on the substrate, the stacked body including a first stacked portion and a second stacked portion formed of alternatingly stacked first layers comprising silicon and nitrogen and second layers comprising silicon and oxygen, the first and second layers being stacked in a first direction on the substrate, the second stacked portion being at an end of the first stacked portion in a second direction perpendicular to the first direction, the second stacked portion having a stepwise structure recessed, with respect to the first stacked portion, towards the substrate in the first direction; and
a third layer on the second stacked portion, the third layer comprising silicon and oxygen, and
a first opening along the first direction in the first stacked portion is simultaneously formed in the plasma etching with a second opening along the first direction in the third layer.

14. An etching apparatus, comprising:
a chamber;
a supplier that introduces, into the chamber, a gas into the chamber, a first substance and a second substance, the first substance including at least one of hydrogen or a halogen, the second substance including a hydroxy group;
electrodes to generate plasma in the chamber from the gas by applying an AC voltage;
a refrigerant pipe in the chamber and configured to cool a workpiece to a temperature of 0° C. or less;
a power source that supplies the AC voltage to the electrodes;
a mass spectrometer that measures a molecular density ratio of HF to H₂O (HF/H₂O) for the gas in the chamber; and
a controller configured to generate the plasma in the chamber while maintaining the molecular density ratio of the gas in the chamber at 0.3 or higher.

15. The etching apparatus of claim 14, wherein the controller is further configured to:
maintain the molecular density ratio (HF/H₂O) for the gas in the chamber at 0.3 to 6.0.

16. The etching apparatus of claim 14, wherein the controller is further configured to:
introduce the gas into the chamber while maintaining a flow rate ratio of H₂O to HF and H₂O (H₂O/(HF+H₂O)) in the gas being introduced to be 0.05 to 0.2.

17. The etching apparatus of claim 14, wherein the first substance comprises at least one material selected from a group consisting of hydrogen, hydrogen fluoride, fluoromethane, difluoromethane, trifluoromethane, ammonia, and phosphine.

18. A method for manufacturing a semiconductor device, the method comprising:
introducing a gas into a chamber, the gas comprising a first substance and a second substance, the first substance including at least one of hydrogen or a halogen, the second substance including a hydroxy group;
generating a plasma in the chamber with the gas therein while maintaining a molecular density ratio of HF to H₂O (HF/H₂O) for the gas in the chamber at 0.3 or higher; and
plasma etching a portion of a workpiece being cooled at to a temperature of 0° C. or less in the chamber, wherein
the workpiece includes:
a substrate;
a stacked body on the substrate, the stacked body including a first stacked portion and a second stacked portion formed by alternatingly stacked first layers comprising silicon and nitrogen and second layers comprising silicon and oxygen, the first and second layers being stacked in a first direction on the substrate, the second stacked portion being at an end of the first stacked portion in a second direction perpendicular to the first direction, the second stacked portion having a stepwise structure, with respect to the first stacked portion, towards the substrate in the first direction; and
a third layer on the second stacked portion, the third layer comprising silicon and oxygen, and
a first opening along the first direction in the first stacked portion being simultaneously formed in the plasma etching with a second opening along the first direction in the third layer.

19. The method of claim 18, further comprising:
maintaining the molecular density ratio (HF/H₂O) for the gas in the chamber at 0.3 to 6.0.

20. The method of claim 18, further comprising:
introducing the gas into the chamber while maintaining a flow rate ratio of H₂O to HF and H₂O (H₂O/(HF+H₂O)) in the gas being introduced to be 0.05 to 0.2.
